(19) United States
(12) Patent Application Publication
(10) Pub. No.: US 2025/0294845 A1
(43) Pub. Date: Sep. 18, 2025

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Hiroki NEMOTO, Meguro Tokyo (JP); Tomoaki INOKUCHI, Yokohama Kanagawa (JP); Masaharu SHIMABAYASHI, Minato Tokyo (JP); Yusuke KOBAYASHI, Yokohama Kanagawa (JP); Shotaro BABA, Kawasaki Kanagawa (JP); Hiro GANGI, Marugame Kagawa (JP); Taichi FUKUDA, Yokohama Kanagawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/062,180

(22) Filed: Feb. 25, 2025

(30) Foreign Application Priority Data
Mar. 13, 2024 (JP) 2024-039358

(51) Int. Cl. H10D 64/23; H10D 30/66; H10D 62/10; H10D 64/00; H10D 64/27; H10D 64/64

(52) U.S. Cl. CPC H10D 64/2527; H10D 30/668; H10D 62/116; H10D 64/647; H10D 64/117; H10D 64/513

(57) ABSTRACT

A plurality of mesas each includes a channel part positioned between recess and a gate electrode in a first direction, and a contact part located on the channel part, the contact part having a higher first-conductivity-type impurity concentration than the channel part. The channel part includes a first side surface facing the gate electrode in the first direction, and a second side surface positioned at a side opposite to the first side surface in the first direction. The insulating film is located at the second side surface. A second electrode contacts the contact part and the insulating film in the recess.

### CROSS-REFERENCE TO RELATED APPLICATION

This application is based upon and claims the benefit of priority from Japanese Patent Application No. 2024-039358, filed on Mar. 13, 2024; the entire contents of which are incorporated herein by reference.

### FIELD

Embodiments described herein relate generally to a semiconductor device.

### BACKGROUND

Among vertical MOSFETS (Metal-Oxide-Semiconductor Field-Effect Transistors), a Schottky MOSFET has been proposed in which a p-type base layer is not included, and an off-state is realized by a depletion layer extending from a Schottky junction between a source electrode and a semiconductor layer at a trench contact part.

### BRIEF DESCRIPTION OF THE DRAWINGS

FIG. 1 and FIG. 2 are schematic cross-sectional views of a semiconductor device of an embodiment; and

FIG. 3A to FIG. 7B are schematic cross-sectional views showing a method for manufacturing the semiconductor device of the embodiment.

### DETAILED DESCRIPTION

According to one embodiment, a semiconductor device includes a first electrode; a semiconductor layer located on the first electrode, the semiconductor layer being of a first conductivity type, the semiconductor layer including a plurality of mesas arranged to be separated from each other in a first direction; a second electrode extending from upper surfaces of the plurality of mesas into recesses of the plurality of mesas, the recesses extending in a second direction orthogonal to the first direction; a gate electrode positioned between mesas adjacent to each other in the first direction among the plurality of mesas; and an insulating film positioned in the recesses, the insulating film being a single-layer insulating film, the plurality of mesas each including a channel part positioned between the recess and the gate electrode in the first direction, and a contact part located on the channel part, the contact part having a higher first-conductivity-type impurity concentration than the channel part, the channel part including a first side surface facing the gate electrode in the first direction, and a second side surface positioned at a side opposite to the first side surface in the first direction, the insulating film being located at the second side surface, the second electrode contacting the contact part and the insulating film in the recess.

Exemplary embodiments will now be described with reference to the drawings.

The drawings are schematic or conceptual; and the relationships between the thickness and width of portions, the proportional coefficients of sizes among portions, etc., are not necessarily the same as the actual values thereof. Furthermore, the dimensions and proportional coefficients may be illustrated differently among drawings, even for identical portions.

In the specification of the application and the drawings, components similar to those described in regard to a drawing thereinabove are marked with like reference numerals, and a detailed description is omitted as appropriate.

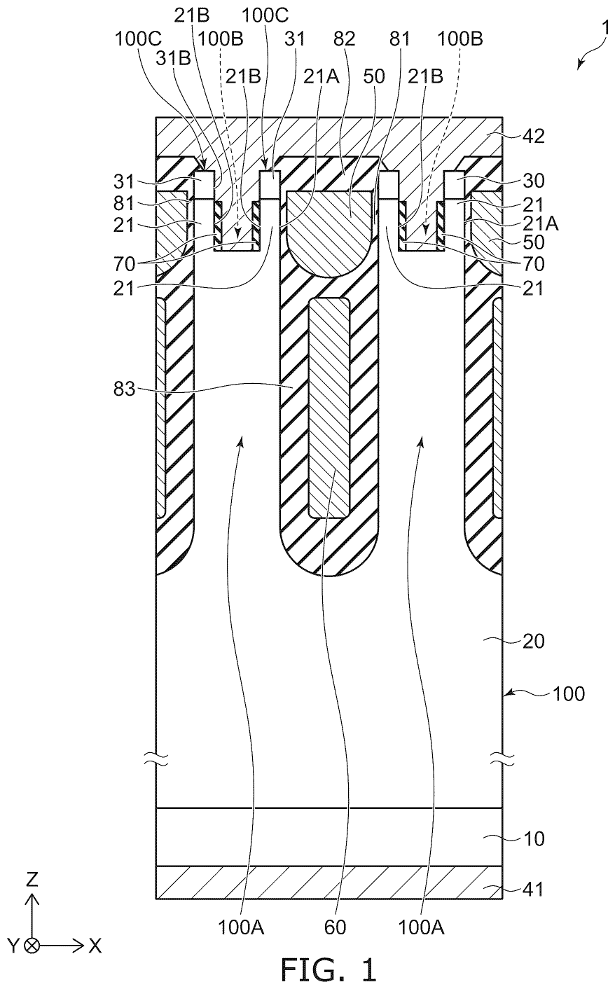

As shown in FIG. 1, a semiconductor device 1 of the embodiment includes a first electrode 41, a semiconductor layer 100 located on the first electrode 41, and a second electrode 42 located on the semiconductor layer 100. The semiconductor device 1 has a vertical MOSFET structure in which a current flows in the thickness direction of the semiconductor layer 100 located between the first electrode 41 and the second electrode 42. The first electrode 41 functions as a drain electrode; and the second electrode 42 functions as a source electrode. The first electrode 41 and the second electrode 42 include a metal.

The thickness direction of the semiconductor layer 100 is along a second direction Z. Two directions orthogonal to the second direction Z are taken as a first direction X and a third direction Y. In FIG. 1, the first direction X is a lateral direction; the second direction Z is a vertical direction; and the third direction Y is a direction extending through the page surface.

The semiconductor layer 100 is of a first conductivity type. Although the first conductivity type is taken to be an n-type in the description of the specification, the first conductivity type may be a p-type. The semiconductor layer 100 is, for example, a silicon layer. Or, the semiconductor layer 100 may be a silicon carbide layer, a gallium nitride layer, etc.

The semiconductor layer 100 includes an n-type first semiconductor layer 10 located on the first electrode 41, an n-type second semiconductor layer 20 located on the first semiconductor layer 10, and an n-type third semiconductor layer 30 located on the second semiconductor layer 20. The n-type impurity concentration of the first semiconductor layer 10 is greater than the n-type impurity concentration of the second semiconductor layer 20. The first semiconductor layer 10 is electrically connected with the first electrode 41 and functions as the drain layer of the MOSFET. The n-type impurity concentration of the second semiconductor layer 20 is less than the n-type impurity concentration of the first semiconductor layer 10 and the n-type impurity concentration of the third semiconductor layer 30. The second semiconductor layer 20 functions as the drift layer of the MOSFET. The n-type impurity concentration of the third semiconductor layer 30 is greater than the n-type impurity concentration of the second semiconductor layer 20. The third semiconductor layer 30 is electrically connected with the second electrode 42 and functions as the source layer of the MOSFET. In the semiconductor layer 100, a p-type base layer is not located between the second semiconductor layer 20 (the drift layer) and the third semiconductor layer 30 (the source layer). The semiconductor device 1 has a Schottky MOSFET structure. Unless otherwise noted hereinbelow, the magnitude relationship of the impurity concentration can be read as the magnitude relationship of the carrier concentration.

The semiconductor layer 100 includes a base part extending in the first and third directions X and Y, and multiple mesas 100A arranged to be separated from each other in the first direction X. The mesas 100A are positioned at the upper surface side of the semiconductor layer 100 at which the second electrode 42 is positioned. The base part is positioned between the first electrode 41 and gate electrodes 50 in the second direction Z. Each mesa 100A includes the third semiconductor layer 30 and a portion of the second semiconductor layer 20.

The semiconductor device 1 includes the gate electrode 50 positioned between the mesas 100A adjacent to each other in the first direction X. The semiconductor device 1 includes, for example, multiple gate electrodes 50. The mesa 100A and the gate electrode 50 are alternately arranged in the first direction X. The mesa 100A and the gate electrode 50 extend in the third direction Y. For example, polycrystalline silicon can be used as the material of the gate electrode 50.

The mesa 100A includes a recess 100B that is open at the upper surface side. The recess 100B extends in the second direction Z from the upper surface of the mesa 100A. The recess 100B also extends in the third direction Y. One mesa 100A includes two sidewall parts 100C separated in the first direction X by the recess 100B. The recess 100B is positioned between the two sidewall parts 100C arranged to be separated from each other in the first direction X. The bottom of the recess 100B is positioned between two gate electrodes 50 adjacent to each other in the first direction X.

The sidewall part 100C includes a channel part 21 and a contact part 31. The channel part 21 is included in the second semiconductor layer 20. The channel part 21 is positioned between the recess 100B and the gate electrode 50 in the first direction X. The contact part 31 is located on the channel part 21 and included in the third semiconductor layer 30. The n-type impurity concentration of the contact part 31 is greater than the n-type impurity concentration of the channel part 21. The n-type carrier concentration of the contact part 31 is greater than the n-type carrier concentration of the channel part 21. For example, the p-type impurity concentration of the contact part 31 is less than the p-type impurity concentration of the channel part 21. In such a case, the n-type impurity concentration of the contact part 31 and the n-type impurity concentration of the channel part 21 may be, for example, equal.

The channel part 21 includes a first side surface 21A facing the side surface of the gate electrode 50 in the first direction X, and a second side surface 21B positioned at the side opposite to the first side surface 21A in the first direction X.

The semiconductor device 1 includes an insulating film 70 positioned in the recess 100B. The insulating film 70 is located at the second side surface 21B of the channel part 21. The insulating film 70 is a single-layer film and is, for example, a silicon oxide film. Or, a silicon nitride film may be used as the insulating film 70.

The semiconductor device 1 includes a gate insulating film 81 located between the first side surface 21A of the channel part 21 and the side surface of the gate electrode 50. The semiconductor device 1 also includes a first inter-layer insulating film 82 located between the gate electrode 50 and the second electrode 42. For example, silicon oxide films can be used as the gate insulating film 81 and the first inter-layer insulating film 82.

The second electrode 42 includes a base part extending in the first and third directions X and Y, and multiple protrusions arranged to be separated from each other in the first direction X. Each protrusion is positioned between the first electrode 41 and the base part of the second electrode 42 in the second direction Z. In the example, one protrusion contacts one mesa 100A. The second electrode 42 is positioned in the recess 100B. The second electrode 42 also is positioned on the contact part 31 and on the first inter-layer insulating film 82. The second electrode 42 contacts the upper surface of the contact part 31. The contact part 31 is positioned in the recess 100B, and includes an inner side surface 31B that is continuous with the second side surface 21B of the channel part 21. At least a portion of the inner side surface 31B of the contact part 31 is not covered with the insulating film 70; and the second electrode 42 contacts the inner side surface 31B of the contact part 31. The second electrode 42 is electrically connected with the contact part 31 at the upper surface and inner side surface 31B of the contact part 31. The second electrode 42 covers the insulating film 70 and contacts the insulating film 70 in the recess 100B. Although the second electrode 42 and the contact part 31 shown in FIG. 1 face and contact each other in the first and second directions X and Z, the second electrode 42 and the contact part 31 may have a configuration in which the second electrode 42 and the contact part 31 face and contact each other in the first direction X but do not contact each other in the second direction Z.

In the first direction X, the insulating film 70 is positioned between the second electrode 42 and the channel part 21 inside the recess 100B; the channel part 21 is positioned between the insulating film 70 and the gate insulating film 81; and the gate insulating film 81 is positioned between the channel part 21 and the gate electrode 50. The channel part 21 contacts the insulating film 70 and the gate insulating film 81. Only one channel part 21 is positioned between the gate electrode 50 and the protrusion of the second electrode 42 that are adjacent to each other in the first direction X. Only one gate electrode 50 or only one protrusion of the second electrode 42 is positioned between two channel parts 21 adjacent to each other in the first direction X. The contact part 31 is positioned between the channel part 21 and the second electrode 42 in the second direction Z. In the example, two channel parts 21 are provided for one mesa 100A.

For example, a positive potential (e.g., not less than 20 V and not more than 50 V) is applied to the first electrode 41; and a ground potential is applied to the second electrode 42. When the potential of the gate electrode 50 is less than a threshold voltage in this state, the channel part 21 is depleted by a depletion layer extending from the interface between the insulating film 70 and the second side surface 21B of the channel part 21; and the semiconductor device 1 is set to the off-state. When the potential of the gate electrode 50 reaches or exceeds the threshold voltage, the depletion layer of the channel part 21 disappears or becomes narrow; and the semiconductor device 1 is switched to the on-state. In the on-state, a current flows from the first electrode 41 to the second electrode 42 via the first semiconductor layer 10, the channel part 21 of the second semiconductor layer 20, and the contact part 31 (the third semiconductor layer 30) of the second semiconductor layer 20.

A high breakdown voltage is obtained in the off-state by the depletion of the channel part 21. It is favorable for the width in the first direction X of the channel part 21 to be narrow to easily deplete the channel part 21. According to the embodiment, the width in the first direction X of the channel part 21 is less than the width in the first direction X of the recess 100B. The width in the first direction X of the channel part 21 is, for example, not less than 20 nm and not more than 80 nm. The threshold voltage of the semiconductor device 1 also is dependent on the width in the first direction X of the channel part 21. The width in the first direction X of the channel part 21 is extremely thin; and from the perspective of the degree of difficulty of the processes, it is difficult to adjust the breakdown voltage and threshold voltage of the semiconductor device 1 using the width in the first direction X of the channel part 21.

The breakdown voltage and threshold voltage of the semiconductor device 1 also are dependent on the barrier height between the semiconductor layer 100 and the metal of the second electrode 42. For example, by using a metal such as Pt, Ni, Co, or the like that has a high work function as the second electrode 42, the barrier height between the second electrode 42 and the semiconductor layer 100 can be increased, and the breakdown voltage can be increased.

A comparative example in which the second electrode 42 and the second side surface 21B of the channel part 21 are in direct contact has a problem in which the barrier height derived from the work function of the metal of the second electrode 42 is not obtained due to effects of Fermi level pinning. For example, when Pt is used as the metal of the second electrode 42 and Si is used as the semiconductor layer 100, the ideal barrier height is calculated to be 5.6 eV (work function of Pt)−4.05 eV (electron affinity of Si)−0.05 eV (image-force effect)=1.5 eV. However, the barrier height in an actual sample was 0.8 eV to 0.85 eV. This may cause a reduction of the design margin.

According to the embodiment, by providing the insulating film 70 between the second electrode 42 and the second side surface 21B of the channel part 21, the effects of Fermi level pinning can be reduced, and a barrier height that reflects the work function of the metal of the second electrode 42 can be realized. As a result, the alternatives of the metal of the second electrode 42 can be increased, and the design margin of the semiconductor device 1 can be enlarged.

An electric field easily concentrates at the corners at the bottom surface side of the recess 100B. By providing the insulating film 70 at such corners, the leakage current in the off-state that occurs at such corners can be suppressed.

A simulation was performed to evaluate the effects on the current-voltage characteristic (the I-V characteristic) of the semiconductor device 1 due to the insulating film 70 located at the second side surface 21B of the channel part 21. Calculations were performed using Si as the material of the channel part 21, a silicon oxide film (a SiO₂ film) as the insulating film 70, a work function of the metal of the second electrode 42 of 5.3 eV, and a barrier height between the second electrode 42 and the Si of 1.2 eV. The film thickness (the thickness in the first direction X) of the insulating film 70 was fixed at 10 nm; and the I-V characteristic was calculated by setting the height (the thickness in the second direction Z) of the insulating film 70 from the bottom of the recess 100B to 100 nm, 200 nm, and 280 nm. The height of the insulating film 70 was fixed at 100 nm; and the I-V characteristic was calculated by setting the film thickness of the insulating film 70 to be 10 nm, 50 nm, and 100 nm. The I-V characteristic was substantially the same for the calculation results of each film thickness and height; and it was confirmed that the insulating film 70 did not affect the breakdown voltage of the semiconductor device 1.

The film thickness of the insulating film 70 can be, for example, not less than 1 nm and not more than 10 nm.

For example, the semiconductor device 1 can be used as a switching element in applications such as inverters, motor driving, etc. In such a case, it is desirable for the semiconductor device 1 to include a freewheeling diode function to carry a reverse current generated when switching. It is therefore favorable not to provide the insulating film 70 at the bottom of the recess 100B, and for the second electrode 42 to contact the second semiconductor layer 20 at the bottom of the recess 100B. As a result, a current path during the freewheeling diode operation (a current path that does not go through the channel part) can be ensured.

The semiconductor device 1 can further include a field plate electrode 60 positioned below the gate electrode 50 between the mesas 100A adjacent to each other in the first direction X. For example, polycrystalline silicon can be used as the material of the field plate electrode 60. A second inter-layer insulating film 83 is located between the gate electrode 50 and the field plate electrode 60 and between the field plate electrode 60 and the second semiconductor layer 20. For example, a silicon oxide film can be used as the second inter-layer insulating film 83.

The same potential as the second electrode 42 is applied to the field plate electrode 60. As a result, the electric field (the vertical electric field) that is applied in the second direction Z to the second semiconductor layer 20 can be relaxed, and the breakdown voltage can be increased. The potential that is applied to the field plate electrode 60 is not limited to the same potential as the second electrode 42; and a potential that is lower than the potential of the first electrode 41 can be applied.

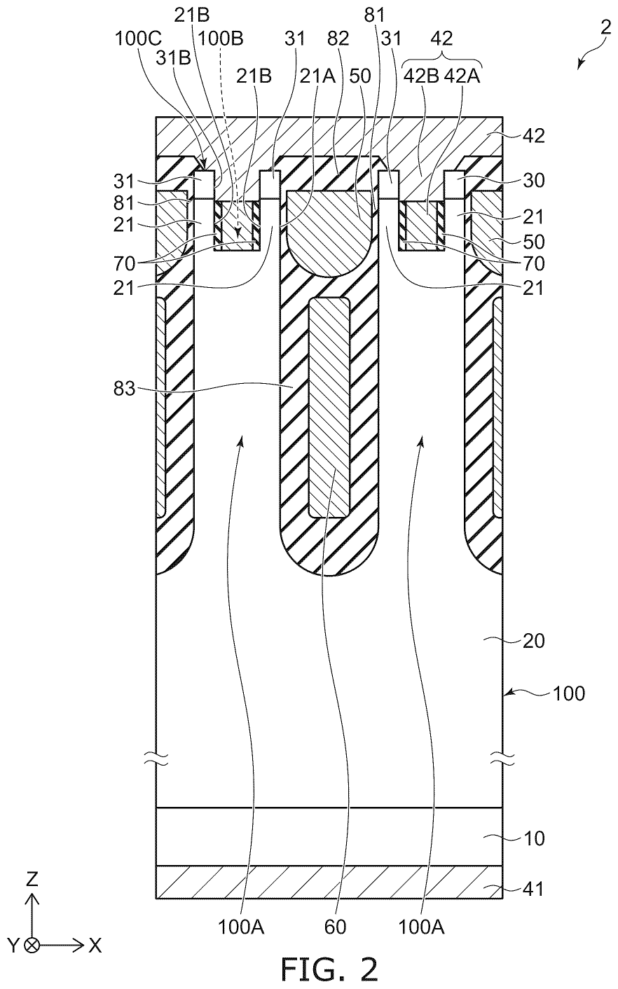

According to a semiconductor device 2 of another embodiment shown in FIG. 2, the second electrode 42 includes a first metal part 42A facing the second side surface 21B of the channel part 21 via the insulating film 70, and a second metal part 42B contacting the inner side surface 31B of the contact part 31. The protrusion of the second electrode 42 includes the first metal part 42A and the second metal part 42B. The work function of the first metal part 42A is greater than the work function of the second metal part 42B. As a result, the contact resistance between the second metal part 42B and the contact part 31 can be reduced while increasing the barrier height between the first metal part 42A and the semiconductor layer 100. For example, the first metal part 42A includes mainly at least one selected from Pt, Ni, and Co; and the second metal part 42B includes mainly Ti.

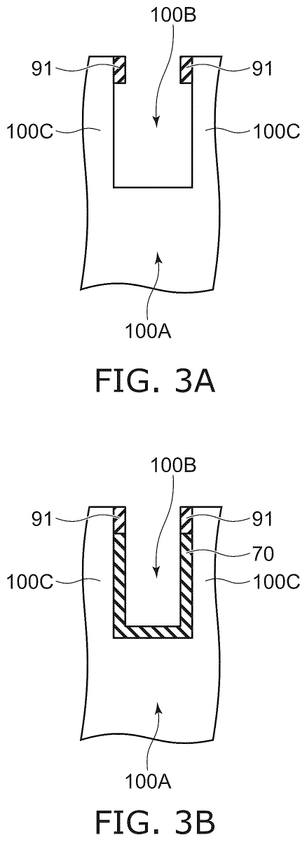

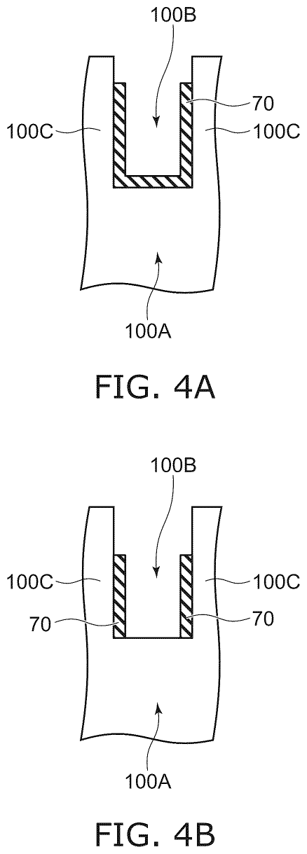

An example of a method for forming the insulating film 70 will now be described with reference to FIGS. 3A to 4B.

The sidewall part 100C is formed at the upper surface side of the mesa 100A by forming the recess 100B in the upper surface side of the mesa 100A. For example, the recess 100B can be formed by RIE (Reactive Ion Etching).

After forming the recess 100B, an inhibition film 91 is formed at the side surface of the recess 100B (the inner side surface of the sidewall part 100C) as shown in FIG. 3A. The inhibition film 91 is formed at the side surface of the recess 100B at the opening side. For example, a resist film can be used as the inhibition film 91.

After forming the inhibition film 91, the insulating film 70 is formed at the side surface and bottom surface of the recess 100B at which the inhibition film 91 is not formed as shown in FIG. 3B. For example, a silicon oxide film can be formed by ALD (Atomic Layer Deposition) as the insulating film 70.

After forming the insulating film 70, the inhibition film 91 is removed. As a result, as shown in FIG. 4A, the side surface of the recess 100B at the opening side is exposed. For example, the inhibition film 91 can be removed by purging and/or etching.

After removing the inhibition film 91, the insulating film 70 is etched by RIE. As a result, as shown in FIG. 4B, the insulating film 70 that is formed at the bottom surface of the recess 100B is removed, and the bottom surface of the recess 100B is exposed. The portion of the sidewall part 100C adjacent to the insulating film 70 is used as the channel part. The contact part that has a higher n-type impurity concentration than the channel part is formed, for example, by ion implantation in the upper portion of the sidewall part 100C. The contact part contacts the second electrode formed inside the recess 100B at the upper portion of the side surface of the recess 100B at which the insulating film 70 is not formed. For example, Pt can be formed inside the recess 100B as the second electrode by sputtering.

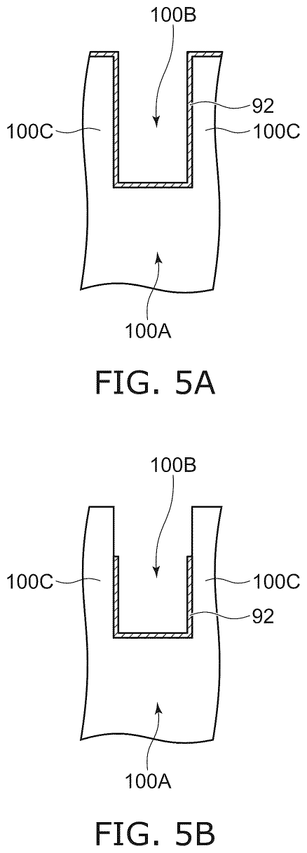

Another example of a method for forming the insulating film 70 will now be described with reference to FIGS. 5A to 7B.

After forming the recess 100B in the mesa 100A, a precursor 92 is formed continuously at the upper surface of the sidewall part 100C and the side surface and bottom surface of the recess 100B as shown in FIG. 5A. For example, a TDMAS (trisdimethylsilane) precursor can be formed as the precursor 92 by ALD.

After forming the precursor 92, a portion of the precursor 92 is removed as shown in FIG. 5B. The precursor 92 at the upper surface of the sidewall part 100C and the precursor 92 at the side surface of the recess 100B at the opening side are removed. The precursor 92 at the side surface of the recess 100B and the precursor 92 at the bottom surface of the recess 100B at the bottom surface side remain. For example, a portion of the precursor 92 can be removed using a reduced-pressure atmosphere and/or O₂ plasma gas.

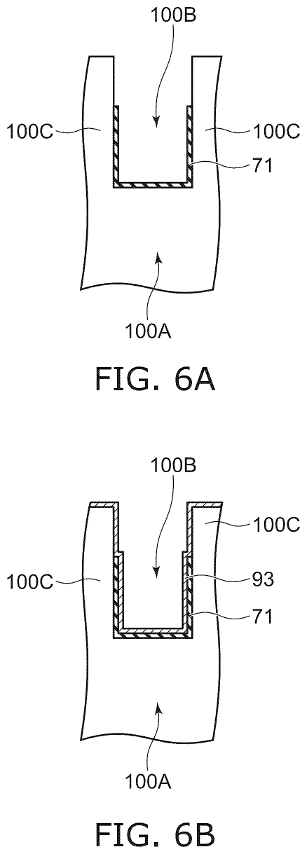

After removing the portion of the precursor 92, the remaining precursor 92 is converted into SiO₂ by supplying, for example, O₂ plasma and/or O₃ gas). As a result, as shown in FIG. 6A, a SiO₂ film 71 is formed at the side surface and bottom surface of the recess 100B at the bottom surface side.

After converting the precursor 92 to SiO₂, a precursor 93 is re-formed at the upper surface of the sidewall part 100C and the side surface and bottom surface of the recess 100B. As shown in FIG. 6B, the precursor 93 covers the SiO₂ film 71 formed in the previous process.

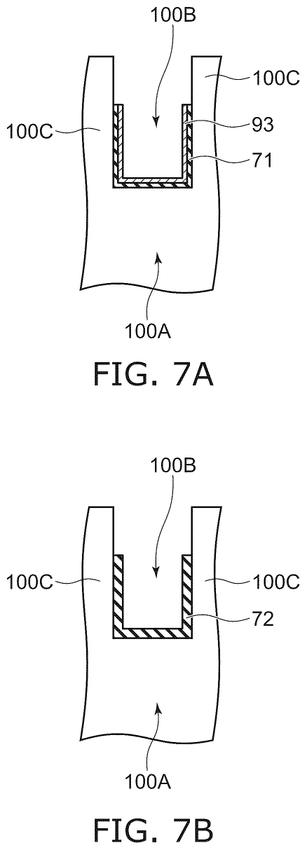

After forming the precursor 93, a portion of the precursor 93 is removed as shown in FIG. 7A. The precursor 93 at the upper surface of the sidewall part 100C and the precursor 93 at the side surface of the recess 100B at the opening side are removed. The precursor 93 that is stacked on the SiO₂ film 71 remains.

After removing the portion of the precursor 93, the remaining precursor 93 is converted to SiO₂. As a result, as shown in FIG. 7B, the SiO₂ film 72 is formed at the side surface and bottom surface of the recess 100B at the bottom surface side. The SiO₂ film 72 is a film formed as a continuous body from the film of the precursor 92 converted to SiO₂ and the film of the precursor 93 converted to SiO₂. Thereafter, the process of re-forming the precursor, the process of removing a portion of the precursor, and the process of converting the precursor to SiO₂ are repeated until the SiO₂ film formed at the side surface and bottom surface of the recess 100B at the bottom surface side has the desired thickness.

Subsequently, the SiO₂ film that is formed at the bottom surface of the recess 100B is removed by etching the SiO₂ film by RIE. As a result, the insulating film 70 that has the desired thickness is formed at the side surface of the recess 100B at the bottom surface side.

The insulating film 70 is a single-layer film. The manufacturing processes of the insulating film 70 that is a single-layer film are simple. The film thickness of the insulating film 70 that is a single-layer film does not fluctuate; effects due to the crystal quality at the stacked film interface are small; and the quality is stable.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device, comprising:
a first electrode;
a semiconductor layer located on the first electrode, the semiconductor layer being of a first conductivity type, the semiconductor layer including a plurality of mesas arranged to be separated from each other in a first direction;
a second electrode extending from upper surfaces of the plurality of mesas into recesses of the plurality of mesas, the recesses extending in a second direction orthogonal to the first direction;
a gate electrode positioned between mesas adjacent to each other in the first direction among the plurality of mesas; and
an insulating film positioned in the recesses, the insulating film being a single-layer insulating film,
the plurality of mesas each including
a channel part positioned between the recess and the gate electrode in the first direction, and
a contact part located on the channel part, the contact part having a higher first-conductivity-type impurity concentration than the channel part,
the channel part including
a first side surface facing the gate electrode in the first direction, and
a second side surface positioned at a side opposite to the first side surface in the first direction,
the insulating film being located at the second side surface,
the second electrode contacting the contact part and the insulating film in the recess.

2. The device according to claim 1, wherein
the second electrode contacts the semiconductor layer at a bottom of the recess.

3. The device according to claim 1, wherein
the second electrode includes:
a first metal part facing the channel part via the insulating film; and
a second metal part contacting the contact part, and
a work function of the first metal part is greater than a work function of the second metal part.

4. The device according to claim 3, wherein
the first metal part includes Pt, Ni, or Co, and
the second metal part includes Ti.

5. The device according to claim 1, wherein
a width in the first direction of the channel part is less than a width in the first direction of the recess.

6. The device according to claim 1, wherein
the semiconductor layer includes:
a first semiconductor layer located on the first electrode;
a second semiconductor layer located on the first semiconductor layer, the second semiconductor layer including the channel part, the second semiconductor layer having a lower first-conductivity-type impurity concentration than the first semiconductor layer; and
a third semiconductor layer located on the second semiconductor layer, the third semiconductor layer including the contact part, the third semiconductor layer having a higher first-conductivity-type impurity concentration than the second semiconductor layer.

7. The device according to claim 1, wherein
the insulating film is a silicon oxide film.

8. The device according to claim 1, wherein
a film thickness of the insulating film is not less than 1 nm and not more than 10 nm.

9. The device according to claim 1, further comprising:
a field plate electrode positioned below the gate electrode between the mesas adjacent to each other in the first direction.

10. The device according to claim 9, wherein
a same potential as the second electrode is applied to the field plate electrode.

11. A semiconductor device, comprising:
a first electrode;
a semiconductor layer located on the first electrode, the semiconductor layer being of a first conductivity type, the semiconductor layer including a plurality of mesas arranged to be separated from each other in a first direction;
a second electrode extending from upper surfaces of the plurality of mesas into recesses of the plurality of mesas, the recesses extending in a second direction orthogonal to the first direction;
a gate electrode positioned between mesas adjacent to each other in the first direction among the plurality of mesas; and
an insulating film positioned in the recesses, the insulating film being a single-layer insulating film,
the plurality of mesas each including
a channel part positioned between the recess and the gate electrode in the first direction, and
a contact part located on the channel part, the contact part having a lower second-conductivity-type carrier concentration than the channel part,
the channel part including
a first side surface facing the gate electrode in the first direction, and
a second side surface positioned at a side opposite to the first side surface in the first direction,
the insulating film being located at the second side surface,
the second electrode contacting the contact part and the insulating film in the recess.

12. A semiconductor device, comprising:
a first electrode;
a semiconductor layer located on the first electrode, the semiconductor layer being of a first conductivity type, the semiconductor layer including a plurality of mesas arranged to be separated from each other in a first direction;
a second electrode extending from upper surfaces of the plurality of mesas into recesses of the plurality of mesas, the recesses extending in a second direction orthogonal to the first direction;
a gate electrode positioned between mesas adjacent to each other in the first direction among the plurality of mesas; and
an insulating film positioned in the recesses, the insulating film being a single-layer insulating film,
the plurality of mesas each including
a channel part positioned between the recess and the gate electrode in the first direction, and
a contact part located on the channel part, the contact part having a higher first-conductivity-type carrier concentration than the channel part,
the channel part including
a first side surface facing the gate electrode in the first direction, and
a second side surface positioned at a side opposite to the first side surface in the first direction,
the insulating film being located at the second side surface,
the second electrode contacting the contact part and the insulating film in the recess.
